(19) United States
(12) Patent Application Publication
(10) Pub. No.: US 2013/0075567 A1
(43) Pub. Date: Mar. 28, 2013

(54) HEAT DISSIPATING DEVICE SUPPORTING APPARATUS

(71) Applicants: GAO-HUI FU, Wuhan City (CN); LI-FU XU, Wuhan City (CN)

(72) Inventors: GAO-HUI FU, Wuhan City (CN); LI-FU XU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/483,293

(22) Filed: May 30, 2012

(30) Foreign Application Priority Data
Sep. 26, 2011 (CN) 201110287866.1

(51) Int. Cl. H05K 7/20

(52) U.S. Cl. 248/346.04

(57) ABSTRACT

A heat dissipating device supporting apparatus includes a base, and a securing element mounted to the mounting portion. The base includes a main body configured to support a heat dissipating device and a mounting portion extending from the main body. The securing element includes a fastener, an elastic member, and a mounting member. The mounting member includes a cavity portion, a supporting portion extending from the cavity portion, and a protrusion extending from an inner side the cavity portion. The supporting portion defines a through hole. The fastener includes a head portion and a shaft portion extending from the head portion. A cross-section of the head portion is greater than that of the shaft portion. The shaft portion is located in the through hole. The elastic member resists resiliently between the head portion and the supporting portion. The head portion resists between the elastic member and the protrusion.

### BACKGROUND

1. Technical Field

The present disclosure relates to supporting apparatuses, and particularly to a supporting apparatus for a heat dissipating device.

2. Description of Related Art

Heat dissipating devices are mounted on the motherboard of electronic devices, such as a computer or a server, for dissipating heat generated from electronic components in the electronic device. A bracket is provided to support the heat dissipating device. The motherboard defines a plurality of installation holes, and the bracket defines a plurality of mounting holes aligned with the plurality of the installation holes. A plurality of fixing members are inserted into the plurality of mounting holes and the corresponding plurality of installation holes, thereby installing the dissipating device on the motherboard. However, different configurations have installation holes defined in different positions of the motherboards. Therefore, the bracket would need to be designed accordingly which may increase manufacturing cost.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a heat dissipating device supporting apparatus, a heat dissipating device, and a printed circuit board.

FIG. 2 is an exploded, isometric view of the heat dissipating device supporting apparatus of FIG. 1.

FIG. 3 is similar to FIG. 2, but viewed in a different aspect.

FIG. 4 is an exploded, isometric view of the securing element of FIG. 2.

FIG. 5 is a cross-sectional view of the securing element of FIG. 2.

FIG. 6 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

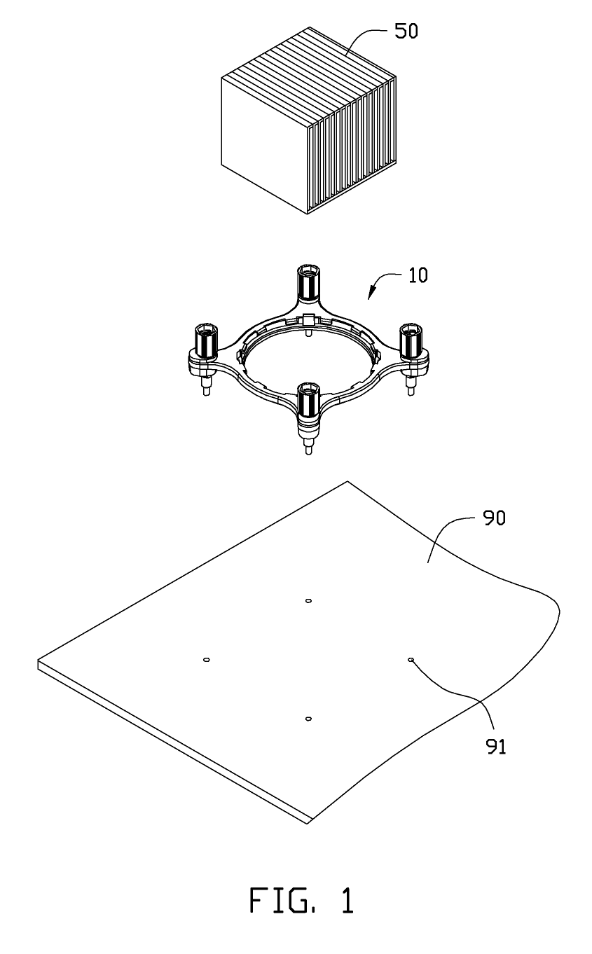

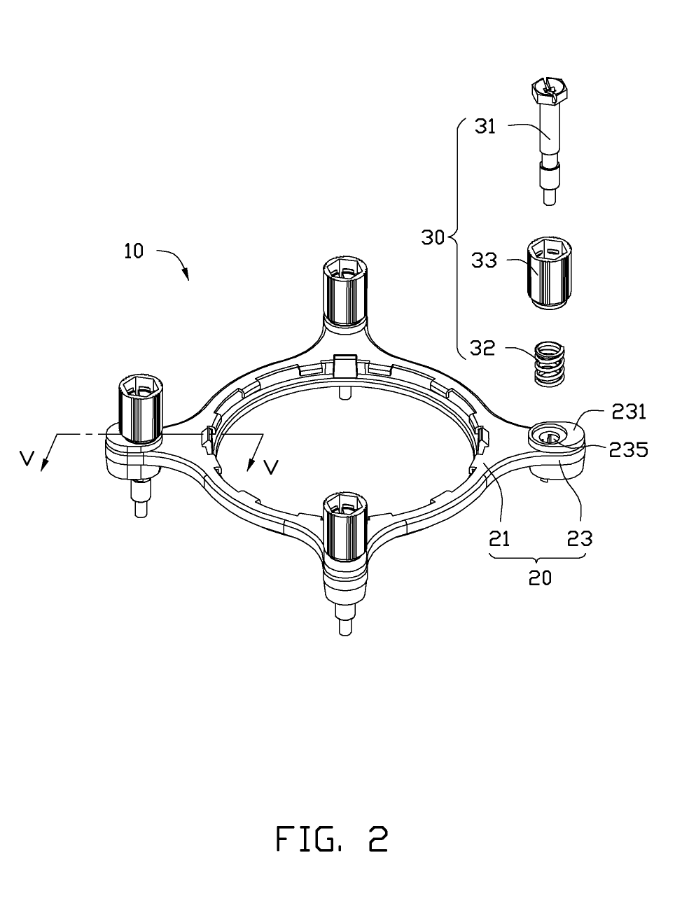

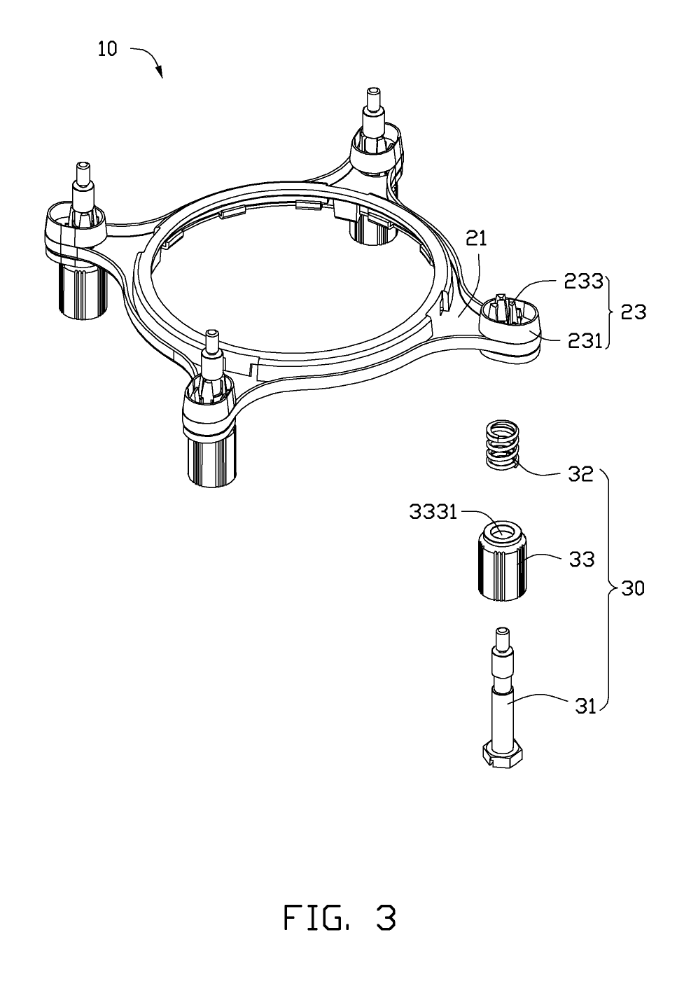

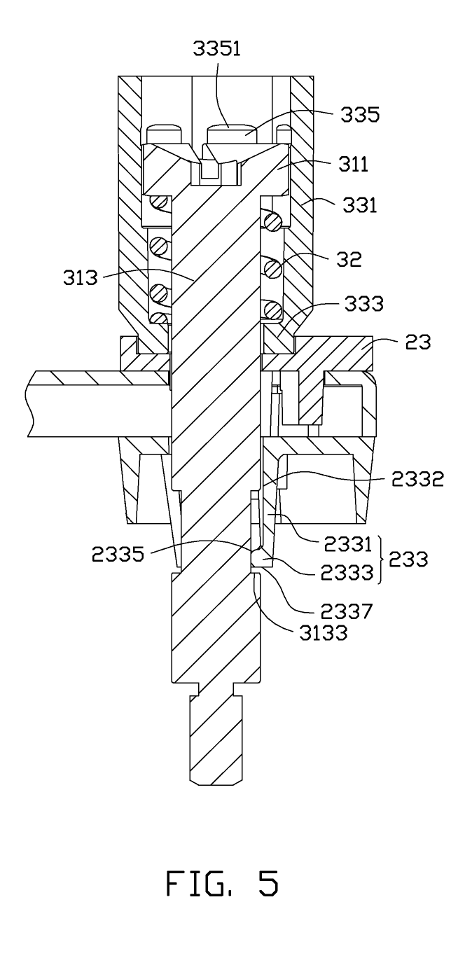

Referring to FIGS. 1-3 and 5, a heat dissipating device supporting apparatus 10 is used for supporting a heat dissipating device 50 on a printed circuit board 90. The heat dissipating device supporting apparatus 10 includes a base 20 and four securing elements 30.

The base 20 includes a main body 21 and four mounting portions 23 extending from the main body 21. Each mounting portion 23 includes a mounting body 231 and a plurality of resisting portions 233 extending substantially perpendicularly from the mounting body 231. The mounting body 231 defines a mounting hole 235. Each resisting portion 233 includes a connecting arm 2331 extending substantially perpendicularly from the mounting body 231 and a stopper portion 2333 extending from the connecting arm 2331. The stopper portion 2333 defines a guiding surface 2335 connected to an inner surface 2332 of the connecting arm 2331 and a resisting surface 2337 connected to the guiding surface 2335. The resisting surface 2337 is substantially perpendicular to the inner surface 2332. The guiding surface 2335 is curved.

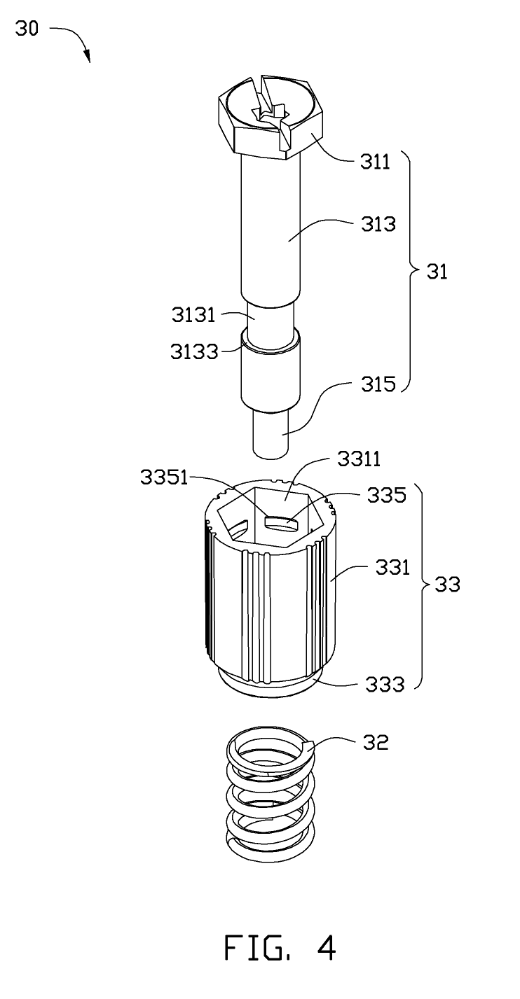

Referring to FIGS. 1, 3, and 4, the securing element 30 includes a fastener 31, an elastic member 32, and a mounting member 33. The fastener 31 includes a head portion 311, a shaft portion 313 extending from the head portion 311, and a securing portion 315 extending from the shaft portion 313. In one embodiment, the elastic member 32 is a spring. The shaft portion 313 includes a recess portion 3131. The recess portion 3131 defines a stopper surface 3133 substantially parallel to the resisting surface 2337. The shaft portion 313 and the securing portion 315 are column-shaped. A cross-section of the shaft portion 313 is greater than a cross-section of the securing portion 315, and less than a cross-section of the head portion 311. The cross-section of the head portion 311 is hexagon-shaped.

The mounting member 33 includes a cavity portion 331, a supporting portion 333 extending from the cavity portion 331, and a plurality of protrusions 335 protruding from an inner side of the cavity portion 331. Each protrusion 335 defines an inclining surface 3351. The cavity portion 331 defines a receiving opening 311 corresponding to the head portion 311. The receiving opening 311 is hexagon-shaped. The supporting portion 333 is substantially circular. The supporting portion 333 defines a through hole 3331 communicating with the receiving opening 3311.

The printed circuit board 90 includes a heat generating element (not shown). The printed circuit board 90 defines four securing holes 91 surrounding the heat generating element.

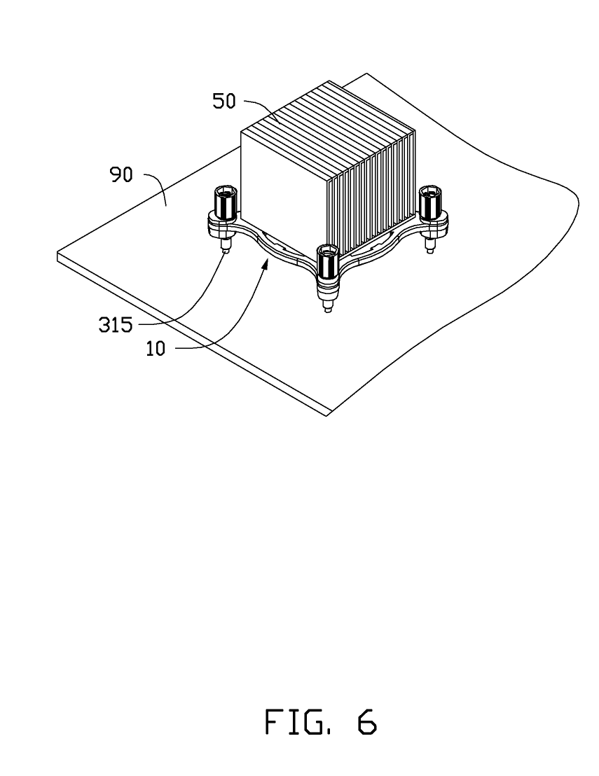

Referring to FIGS. 1 to 6, in assembly of the heat dissipating device supporting apparatus 10, the elastic member 32 of the securing element 30 is placed in the receiving opening 3311 of the mounting member 33 to be located on the supporting portion 333. The shaft portion 313 and the securing portion 315 of each fastener 31 pass through the elastic member 32 and the through hole 3331 to enable the head portion 311 to engage the protrusions 335 by the inclining surfaces 3351. At this time, the elastic member 32 resists resiliently between the head portion 311 and the supporting portion 333. The head portion 311 resists between the elastic member 32 and the protrusions 335. The shaft portion 313 of each securing element 30 is inserted into the mounting hole 235 of the base 20 along a first direction. The shaft portion 313 resists the guiding surfaces 2335 of the stopper portions 2333 to enable the connecting arm 2331 to be distorted, which drives the stopper portions 2333 to extend outward. The connecting arms 2331 release to enable the stopper portions 2333 to engage in the recess portions 3131. The stopper surface 3133 is configured to resist the resisting surface 2337 to stop the securing elements 30 from moving out of the mounting holes 235 along a second direction substantially opposite to the first direction.

The heat dissipating device 50 is placed on the heat dissipating device supporting apparatus 10. The securing portions 315 of the heat dissipating device supporting apparatus 10 are aligned with the securing holes 91 of the printed circuit board 90. The mounting members 33 are rotated to drive the corresponding fasteners 31 to screw into the corresponding securing holes 91.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A heat dissipating device supporting apparatus comprising:
a base comprising a main body configured to support a heat dissipating device and a mounting portion extending from the main body; and
a securing element mounted to the mounting portion, the securing element comprising a fastener, an elastic member, and a mounting member, wherein the mounting member comprises a cavity portion, a supporting portion extends from the cavity portion, and a protrusion extends from an inner side the cavity portion; the supporting portion defines a through hole; the fastener comprises a head portion and a shaft portion extending from the head portion, a cross-section of the head portion being greater than a cross-section of the shaft portion; the shaft portion is located in the through hole and exposed out of the cavity portion; the elastic member elastically resists the head portion and the supporting portion, and the head portion resists the elastic member and the protrusion.

2. The heat dissipating device supporting apparatus of claim 1, wherein the mounting portion comprises a mounting body and a resisting portion extending from the mounting body; the mounting body defines a mounting hole; the shaft portion comprises a recess portion; the shaft portion is configured to pass through the mounting hole to enable the resisting portion to engage in the recess portion along a first direction.

3. The heat dissipating device supporting apparatus of claim 2, wherein the resisting portion comprises a connecting arm extending from the mounting body and a stopper portion extending from the connecting arm; the stopper portion comprises a guiding surface connected to an inner surface of the connecting arm and a resisting surface connected to the guiding surface; the recess portion comprises a stopper surface; the stopper surface is configured to resist the resisting surface to stop the shaft portion from moving out of the mounting hole along a second direction substantially opposite to the first direction.

4. The heat dissipating device supporting apparatus of claim 3, wherein the resisting surface is substantially perpendicular to the inner surface.

5. The heat dissipating device supporting apparatus of claim 3, wherein the fastener further comprises a securing portion extending from the shaft portion; a cross-section of the securing portion is less than the cross-section of the shaft portion.

6. The heat dissipating device supporting apparatus of claim 1, wherein the elastic member is a spring, the spring surrounds the shaft portion.

7. The heat dissipating device supporting apparatus of claim 1, wherein the cavity portion and the resisting portion are located on opposite sides of the mounting body.

8. The heat dissipating device supporting apparatus of claim 1, wherein supporting portion is circular.

9. The heat dissipating device supporting apparatus of claim 1, wherein the protrusion comprises an inclining surface configured to guide the head portion to move into the cavity portion.

10. The heat dissipating device supporting apparatus of claim 1, wherein the cavity portion defines a receiving opening corresponding to the head portion, the cavity portion is configured to be rotated to drive the fastener to be rotated.

11. A heat dissipating device supporting apparatus comprising:
a base, the base comprising a main body configured to support a heat dissipating device and a mounting portion extending from the main body, the mounting portion defining a mounting hole; and
a securing element, the securing element comprising a fastener, an elastic member, and a mounting member; the mounting member comprising a cavity portion, a supporting portion extending from the cavity portion, and a protrusion extending from an inner side the cavity portion; the supporting portion defining a through hole corresponding to the mounting hole; the fastener comprising a head portion and a shaft portion extending from the head portion, a cross-section of the head portion greater than a cross-section of the shaft portion; the shaft portion located in the through hole and the mounting hole; the fastener configured to be received cavity portion to enable the head portion to engage the protrusion along a first direction, the elastic member resisting resiliently between the head portion and the supporting portion, the protrusion configured to stop the head portion from moving along a second direction substantially opposite to the first direction.

12. The heat dissipating device supporting apparatus of claim 11, wherein the mounting portion comprises a mounting body and a resisting portion extending from the mounting body; the mounting hole is defined in the mounting body; the shaft portion comprises a recess portion; the resisting portion engages in the recess portion.

13. The heat dissipating device supporting apparatus of claim 12, wherein the resisting portion comprises a connecting arm extending from the mounting body and a stopper portion extending from the connecting arm; the stopper portion comprises a guiding surface connected to an inner surface of the connecting arm and a resisting surface connected to the guiding surface; the recess portion comprises a stopper surface; the stopper surface is configured to resist the resisting surface to stop the shaft portion from moving out of the mounting hole.

14. The heat dissipating device supporting apparatus of claim 13, wherein the resisting surface is substantially perpendicular to the inner surface.

15. The heat dissipating device supporting apparatus of claim 13, wherein the fastener further comprises a securing portion extending from the shaft portion; a cross-section of the securing portion is less than the cross-section of the shaft portion.

16. The heat dissipating device supporting apparatus of claim 11, wherein the elastic member is a spring, the spring surrounds the shaft portion.

17. The heat dissipating device supporting apparatus of claim 11, wherein the cavity portion and the resisting portion are located on opposite sides of the mounting body.

18. The heat dissipating device supporting apparatus of claim 11, wherein supporting portion is circular.

19. The heat dissipating device supporting apparatus of claim 11, wherein the protrusion comprises an inclining surface configured to guide the head portion to move into the cavity portion.

20. The heat dissipating device supporting apparatus of claim 11, wherein the cavity portion defines a receiving opening corresponding to the head portion, the cavity portion is configured to be rotated to drive the fastener to be rotated.
